(19) United States
(12) Patent Application Publication
(10) Pub. No.: US 2017/0040823 A1
(43) Pub. Date: Feb. 9, 2017

(54) DRIVER CIRCUIT AND SEMICONDUCTOR RELAY INCLUDING THE SAME

(71) Applicant: Panasonic Intellectual Property Management Co., Ltd., Osaka (JP)

(72) Inventors: TAKUYA SUNADA, Osaka (JP); YASUSHI KONISHI, Mie (JP); YU BUNGI, Mie (JP)

(21) Appl. No.: 15/211,737

(22) Filed: Jul. 15, 2016

(30) Foreign Application Priority Data
Aug. 4, 2015 (JP) 2015-154258

(51) Int. Cl. H02J 7/00; H03K 17/687; H02J 7/35; H02M 3/07

(52) U.S. Cl. CPC H02J 7/0072; H02M 3/07; H03K 17/687; H02J 7/35

(57) ABSTRACT

A driver circuit includes an input circuit, a control circuit, and an isolation circuit. The input circuit is configured to generate output signals corresponding to the input signals entered to a pair of input terminals. The input circuit includes an active element configured to driven by the input signals, and a capacitive element electrically connected between the active element and one of the input terminals. The control circuit is configured to send control signals corresponding to the output signals of the input circuit to the output circuit. The isolation circuit includes a plurality of capacitors electrically connected between the input circuit and the control circuit so as to provide electrical isolation between the input circuit and the control circuit.

### BACKGROUND

1. Technical Field

The present disclosure relates to a driver circuit and a semiconductor relay including the circuit. In particular, the present disclosure relates to a driver circuit which provides electrical isolation between the input and the output and also relates to a semiconductor relay including the circuit.

2. Description of the Related Art

Some conventional semiconductor relays include a light-emitting element, a photovoltaic element, and a metal-oxide-semiconductor (MOS) transistor. The light-emitting element emits light based on an input signal. The photovoltaic element receives a light signal from the light-emitting element and generates an electromotive force. The MOS transistor is turned on and off by the electromotive force generated by the photovoltaic element (see, for example, PTL 1).

### CITATION LIST

### Patent Literature

PTL 1: Japanese Unexamined Patent Application Publication No. S64-41319

### SUMMARY

The driver circuit of the present disclosure is electrically connected to a pair of input terminals and an output circuit. The driver circuit includes an input circuit, a control circuit, and an isolation circuit.

The input circuit is configured to generate output signals corresponding to input signals entered to the input terminals.

The input circuit includes an active element and a capacitive element. The active element is configured to be driven by the input signals. The capacitive element is electrically connected between the active element and one of the input terminals.

The control circuit is configured to send control signals corresponding to the output signals of the input circuit to the output circuit. The isolation circuit includes a plurality of capacitors electrically connected between the input circuit and the control circuit so as to provide electrical isolation between the input circuit and the control circuit.

### BRIEF DESCRIPTION OF THE DRAWINGS

FIG. 1 is a circuit diagram of a semiconductor relay including a driver circuit according to an exemplary embodiment;

FIG. 2A is a circuit diagram of an input circuit which includes inverters and is included in the driver circuit according to the exemplary embodiment;

FIG. 2B is a circuit diagram of a modified example of the input circuit which includes inverters and is included in the driver circuit according to the exemplary embodiment;

FIG. 2C is a circuit diagram of another modified example of the input circuit which includes inverters and is included in the driver circuit according to the exemplary embodiment;

FIG. 3 is a circuit diagram of an input circuit which includes an operational amplifier and is included in the driver circuit according to the exemplary embodiment; and

FIG. 4 is a circuit diagram of an input circuit which includes transistors and is included in the driver circuit according to the exemplary embodiment.

### DETAILED DESCRIPTION

The semiconductor relay of PTL 1 needs a comparatively large current to make the light-emitting element emit light.

Driver circuit 1 and semiconductor relay 10 according to the present exemplary embodiment will now be described with reference to drawings. Note that the following exemplary embodiment is one example of the present invention, and the present invention is not limited to this embodiment. Besides this embodiment, various modifications can be made depending on design or other factors within the scope of the technical idea of the present invention.

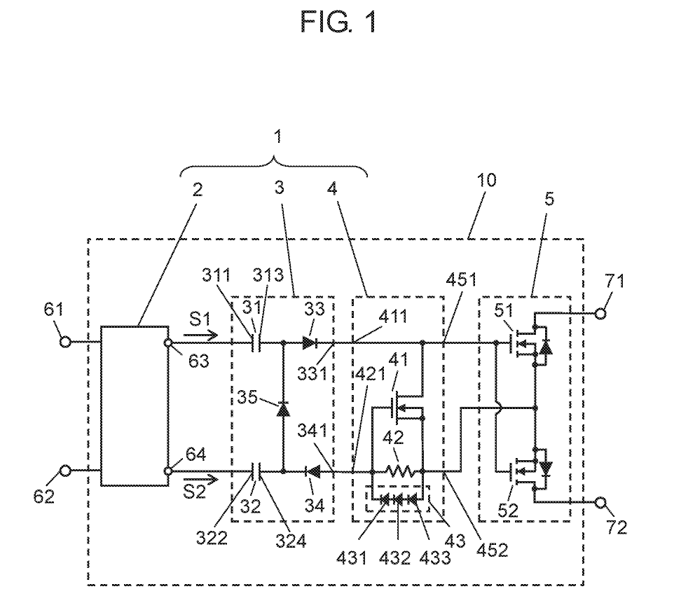

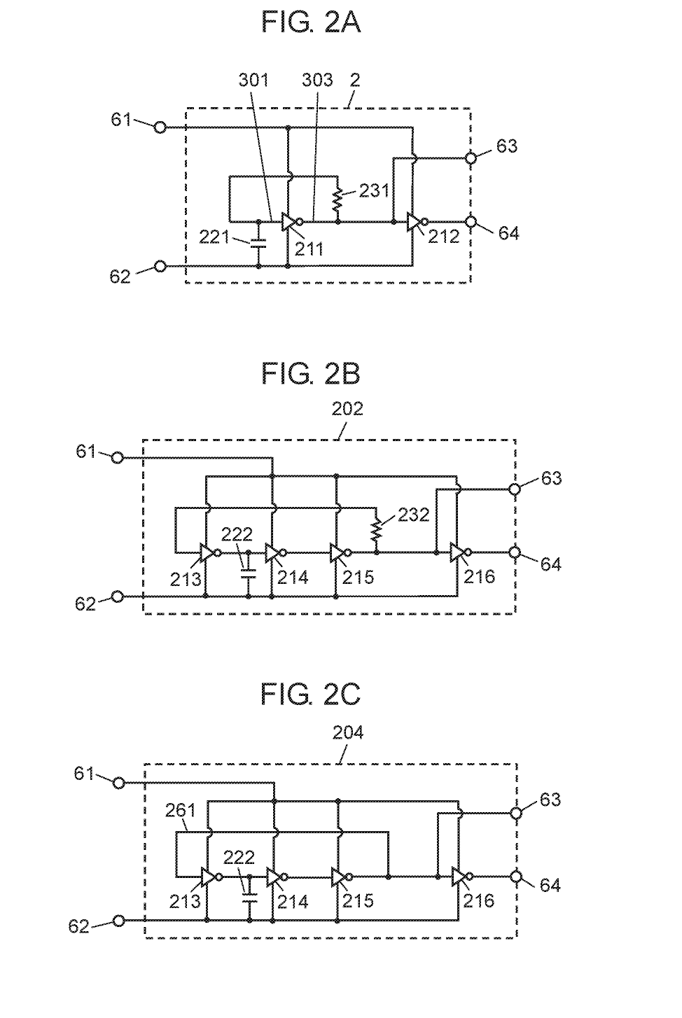

FIG. 1 is a circuit diagram of semiconductor relay 10 including driver circuit 1 according to the exemplary embodiment. FIG. 2A is a circuit diagram of input circuit 2, which includes inverters 211 and 212 and is included in driver circuit 1 according to the exemplary embodiment.

Driver circuit 1 of the present disclosure is electrically connected to a pair of input terminals 61 and 62 and output circuit 5. Driver circuit 1 includes input circuit 2, control circuit 4, and isolation circuit 3.

Input circuit 2 generates output signals corresponding to input signals entered to input terminals 61 and 62.

Input circuit 2 includes an active element (inverter 211) and a capacitive element (capacitor 221). The active element is driven by an input signal. The capacitive element is electrically connected between the active element and one of input terminals 61 and 62.

Control circuit 4 sends to output circuit 5 control signals corresponding to the output signals of input circuit 2.

Isolation circuit 3 includes capacitors 31 and 32, which are electrically connected between input circuit 2 and control circuit 4, thereby providing electrical isolation between input circuit 2 and control circuit 4.

The following is a detailed description of driver circuit 1 and semiconductor relay 10. Driver circuit 1 according to the present exemplary embodiment can be used in relay 10, which is a static relay with no movable contacts, such as a mechanical relay. Relay 10 can be used to control, for example, security devices, amusement devices, medical devices, storage battery systems, heaters, DC motors, etc.

As shown in FIG. 1, semiconductor relay 10 includes driver circuit 1 and output circuit 5, and may further include a pair of input terminals 61 and 62 and a pair of output terminals 71 and 72. Driver circuit 1 includes input circuit 2 (oscillator circuit), isolation circuit 3 (boost circuit), and control circuit 4 (charge-discharge circuit). Output circuit 5 belongs to semiconductor relay 10 but not to driver circuit 1.

Input terminals 61 and 62 are electrically connected to the input ends of input circuit 2. Output terminals 71 and 72 are electrically connected to the output ends of output circuit 5. Input terminals 61 and 62 are also electrically connected to, for example, a microcomputer (not shown) and receive its electrical signals as input signals. Output terminals 71 and 72 are electrically connected to a load (not shown) and a power supply (not shown) which supplies power to the load.

As shown in FIG. 2A, input circuit 2 includes inverters 211 and 212, capacitor 221, resistor 231, and a pair of output terminals 63 and 64. Inverters 211 and 212 receive input signals (electrical signals) from input terminals 61 and 62.

Capacitor 221 is electrically connected between input part 301 of inverter 211 and input terminal 62. Thus, one electrode of capacitor 221 is electrically connected directly to input terminal 62 so as to have a stable potential. Resistor 231 is electrically connected between input part 301 and output part 303 of inverter 211.

Output part 303 of inverter 211 is electrically connected directly to output terminal 63, and is also electrically connected to output terminal 64 through inverter 212. In other words, output terminal 63 outputs an output signal (a first oscillation signal 51) of inverter 211 whereas output terminal 64 outputs an output signal (a second oscillation signal S2) of inverter 211. The signal S2 is generated by inverting the phase of the signal 51 by inverter 212.

In that case, input circuit 2 is the oscillator circuit, inverter 211 is the active element, and capacitor 221 is the capacitive element.

Input circuit 2 including one active element (inverter 211) can be reduced in size and cost, as compared with input circuits including two or more active elements. In the present exemplary embodiment, capacitor 221 alone is used as the capacitive element, but alternatively, two or more capacitive elements can be used.

As shown in FIG. 1, isolation circuit 3 is a charge-pump boost circuit with a plurality of capacitors and diodes. In the present exemplary embodiment, isolation circuit 3 includes capacitors 31 and 32, and diodes 33-35.

Capacitor 31 has first electrode 311 electrically connected to output terminal 63, which is on the high-tension side of input circuit 2. Capacitor 31 also has second electrode 313 electrically connected to the anode of diode 33. Capacitor 32 has first electrode 322 electrically connected to output terminal 64, which is on the on the low-tension side of input circuit 2. Capacitor 32 also has second electrode 324 electrically connected to the cathode of diode 34. The anode of diode 35 is electrically connected to the connection point of capacitor 32 and diode 34, whereas the cathode of diode 35 is electrically connected to the connection point of capacitor 31 and diode 33.

The cathode of diode 33 is electrically connected to first input end 411, which is on the high-tension side of control circuit 4. The anode of diode 34 is electrically connected to second input end 421, which is on the low-tension side of control circuit 4. Capacitor 31 receives the first oscillation signal S1 from input circuit 2 (oscillator circuit), whereas capacitor 32 receives the second oscillation signal S2 from input circuit 2. Isolation circuit 3 (boost circuit) boosts the received first and second oscillation signals S1 and S2, and sends them to control circuit 4 (charge-discharge circuit), which will be described later.

First electrodes 311 and 322 of capacitors 31 and 32, respectively, are electrically connected to input circuit 2 (i.e. the input-side circuit). Second electrodes 313 and 324 of capacitors 31 and 32, respectively, are electrically connected to control circuit 4 (i.e. the output-side circuit). Thus, in driver circuit 1 of the present exemplary embodiment, capacitors 31 and 32 of isolation circuit 3 provide electrical isolation between the input and the output.

Control circuit 4 includes semiconductor device 41, resistor 42, and bypass circuit 43. Semiconductor device 41 is an n-channel depletion-mode metal-oxide-semiconductor (MOS) field-effect transistor (FET). The drain of semiconductor device 41 is electrically connected through first input end 411 to first output end 331, which is on the high-tension of isolation circuit 3. The gate of semiconductor device 41 is electrically connected through second input end 421 to second output end 341, which is on the low-tension side of isolation circuit 3.

The source of semiconductor device 41 is electrically connected through resistor 42 to second output end 341 on the low-tension side of isolation circuit 3. In other words, resistor 42 is electrically connected between the gate and the source of semiconductor device 41.

In addition, bypass circuit 43 is electrically connected between the gate and the source of semiconductor device 41. Bypass circuit 43 is composed of series-connected diodes 431-433. Diodes 431-433 are electrically connected between the gate and the source of semiconductor device 41 in such a manner that their cathodes are on the gate side of semiconductor device 41 and that their anodes are on the source side of semiconductor device 41. In other words, diodes 431-433 are connected in parallel with resistor 42.

Without bypass circuit 43, resistor 42 electrically connected between the gate and the source of semiconductor device 41 would reduce the charging current flowing to later-described semiconductor switches 51 and 52. This would require a long charging time, and hence, a long time before semiconductor relay 10 is turned on.

In contrast, when bypass circuit 43 is connected in parallel with resistor 42 as in the present exemplary embodiment, the charging current flows through bypass circuit 43 to eliminate the influence of resistor 42, thereby increasing the charging current. This reduces the charging time, and hence, the time required before semiconductor relay 10 is turned on.

Meanwhile, some conventional bypass circuits include an enhancement-mode MOSFET. In such bypass circuits, the threshold voltage of the MOSFET needs to be adjusted with the bypass starting voltage. This requires cost and effort for the adjustment during manufacture.

In contrast, bypass circuit 43 composed of diodes 431-433 as in the present exemplary embodiment is not required to adjust the threshold voltage as mentioned above. Bypass circuit 43 is only required to control the number of diodes, thereby eliminating the cost for the adjustment during manufacture. Furthermore, diodes are smaller than MOSFETs, allowing semiconductor relay 10 to be compact.

Meanwhile, in the case of a conventional optically-isolated semiconductor relay, the light from the light-emitting element may cause malfunction of the diodes composing the bypass circuit. In contrast, in capacity-isolated semiconductor relay 10 of the present exemplary embodiment, diodes 431-433 are not exposed to the light. As a result, relay 10 can be turned on and off with no errors.

The number of diodes composing bypass circuit 43 is not limited to three, and can be one, two, or more than three. Bypass circuit 43 is dispensable if it is unnecessary to reduce the time required before relay 10 is turned on.

Output circuit 5 includes semiconductor switches 51 and 52, which are n-channel enhancement-mode MOSFETs. The drain of switch 51 is electrically connected to output terminal 71, whereas the drain of switch 52 is electrically connected to output terminal 72. The gates of switches 51 and 52 are electrically connected to first output end 451, which is on the high-tension side of control circuit 4.

The sources of switches 51 and 52 are electrically connected to second output end 452, which is on the low-tension side of control circuit 4. In other words, switches 51 and 52 are electrically connected in anti-series between output terminals 71 and 72.

The operation of input circuit 2 of the present exemplary embodiment will now be described as follows.

The input voltage applied to inverter 211 is low immediately after input signals are entered to input terminals 61 and 62. As a result, inverter 211 outputs a high potential voltage signal. This voltage signal is applied to capacitor 221 through resistor 231, so that capacitor 221 is in a charged state.

Later, when the input voltage applied to inverter 211 (the voltage of capacitor 221) exceeds the threshold voltage of inverter 211, inverter 211 outputs a low potential voltage signal. As a result, capacitor 221 changes from the charged state to a discharge state to be discharged through resistor 231. Input circuit 2 performs oscillation by repeating the above-described operations.

The following is a description of the operations of driver circuit 1 and semiconductor relay 10 according to the present exemplary embodiment.

When input signals are entered to input terminals 61 and 62, input circuit 2 outputs the first oscillation signal S1 and the second oscillation signal S2. When receiving these signals Si and S2, isolation circuit 3 outputs a voltage signal with substantially twice as high an amplitude as the signal S1 and a voltage signal with substantially twice as high an amplitude as the signal S2.

Immediately after the input signals are entered to input terminals 61 and 62, semiconductor device 41 is in the ON state, and the impedance between the drain and the source of semiconductor device 41 is low. Therefore, the current coming from isolation circuit 3 flows through semiconductor device 41 and resistor 42.

As a result, resistor 42 causes a voltage drop, which allows the impedance between the drain and the source of semiconductor device 41 to change from low to high. In short, device 41 goes into the off state. Therefore, the current coming from isolation circuit 3 flows into the gates of switches 51 and 52 of output circuit 5.

Thus, when input signals are entered to input terminals 61 and 62, the gate capacitances of switches 51 and 52 of control circuit 4 (charge-discharge circuit) are charged. Consequently, the impedance between the drain and the source of each of switches 51 and 52 changes from high to low. As a result, switches 51 and 52 go into the ON state, providing electrical continuity between output terminals 71 and 72.

The term “gate capacitance” indicates the capacitance between the gate and the source (generally referred to as “gate input capacitance”) and the capacitance between the gate and the drain (generally referred to as “gate output capacitance”) of each of switches 51 and 52.

When no more input signals are entered to input terminals 61 and 62, isolation circuit 3 does not output current. As a result, resistor 42 does not cause a voltage drop, and semiconductor device 41 goes into the ON state. This allows the impedance between the drain and the source of device 41 to change from high to low. Hence, the gate capacitances of switches 51 and 52 are rapidly discharged through device 41.

Next, the impedance between the drain and the source of each of switches 51 and 52 change from low to high, allowing switches 51 and 52 to go into the off state.

Thus, while input signal are entered to input terminals 61 and 62, switches 51 and 52 are in the ON state, providing electrical continuity between output terminals 71 and 72. In short, relay 10 of the present exemplary embodiment is in the ON state. On the other hand, while no input signals are entered to input terminals 61 and 62, switches 51 and 52 are in the off state. In short, relay 10 of the present exemplary embodiment is in the off state.

Input circuit 2 may be modified into input circuit 202 as shown in the modified example 1 of FIG. 2B. Input circuit 202 includes a plurality of inverters, capacitor 222, resistor 232, and output terminals 63 and 64. In the present exemplary embodiment, input circuit 202 includes inverters 213-216, but the number of inverters is not limited to four.

The output end of inverter 213 is electrically connected to the input end of inverter 214. The output end of inverter 214 is electrically connected to the input end of inverter 215. Thus, in the modified example 1, inverters 213-215 are electrically connected in series to each other. The input end of inverter 213 is electrically connected to the output end of inverter 215 through resistor 232. Capacitor 222 is electrically connected between the output end of inverter 213 and input terminal 62.

The output end of inverter 215 is electrically connected directly to output terminal 63, and is electrically connected to output terminal 64 through inverter 216. Thus, in input circuit 202, output terminal 63 outputs the first oscillation signal S1, whereas output terminal 64 outputs the second oscillation signal S2. The signal S2 is generated by inverting the phase of the signal S1 by inverter 216. In the modified example 1, inverters 213-215 are the active elements, and capacitor 222 is the capacitive element.

Input circuit 202 including inverters 213 to 215 can be turned on and off surely, and hence, can perform more stable oscillation, as compared with an input circuit including only one inverter.

In input circuit 202, resistor 232 is electrically connected between the input end of inverter 213 and the output end of inverter 215, but may alternatively be located in any other position.

In input circuit 202, capacitor 222 (capacitive element) is electrically connected between the output end of inverter 213 and input terminal 62, but the capacitive element may alternatively be located in any other position. In addition, the number of the capacitive element (capacitor) can be more than one.

Input circuit 2 may be modified into input circuit 204 as shown in the modified example 2 of FIG. 2C. Input circuit 204 is different from input circuit 202 of the modified example 1 in including conductor 261, which electrically connects the input end of inverter 213 and the output end of inverter 215, and in using the parasitic resistance of conductor 261 as a resistor. The other features are identical to those of the modified example 1, and hence, their detailed description will not be repeated here.

In input circuit 204, the parasitic resistance of conductor 261 preferably has as low a resistance as possible so that input circuit 204 can be less subjected to ambient temperature. When the resistance of the parasitic resistance is low, however, input circuit 204 needs adjustment to make the oscillation possible, such as increasing the capacitance of capacitor 222.

In input circuit 204 of the modified example 2, the parasitic capacitances of inverters 213-215 may be the capacitive elements, so that input circuit 204 can be implemented by a smaller number of components, thereby being reduced in size and cost.

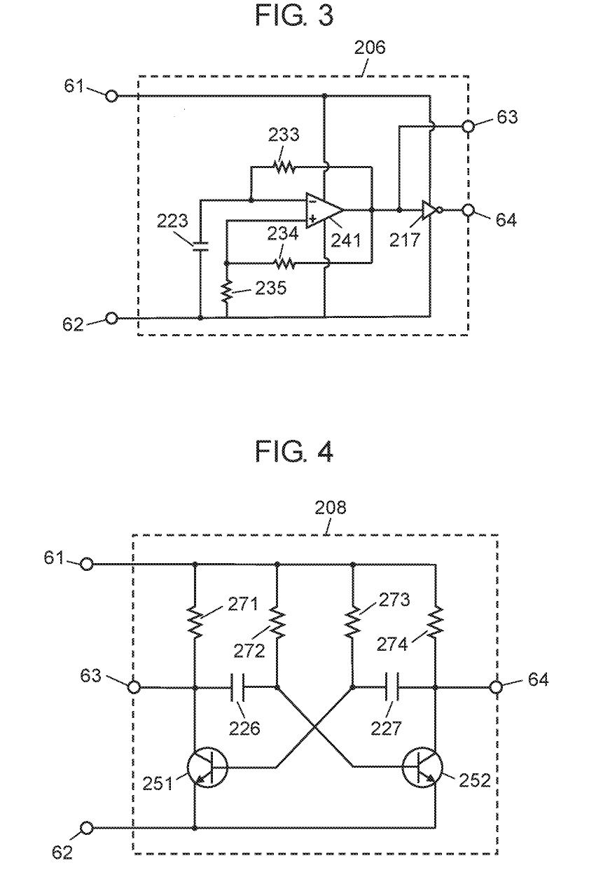

Input circuit 2 may be modified into input circuit 206 as shown in the modified example 3 of FIG. 3. Input circuit 206 includes operational amplifier 241, capacitor 223, a plurality of resistors, inverter 217, and output terminals 63 and 64. Operational amplifier 241 and inverter 217 receive input signals (voltage signals) from input terminals 61 and 62. Input circuit 206 includes resistors 233-235 in the present exemplary embodiment, but the number of resistors is not limited to three.

The inverting input terminal (−) of amplifier 241 is electrically connected to input terminal 62 through capacitor 223. Resistor 233 is electrically connected between the inverting input terminal and the output terminal of amplifier 241.

The non-inverting input terminal (+) of amplifier 241 is electrically connected to input terminal 62 through resistor 235. Resistor 234 is electrically connected between the non-inverting input terminal and the output terminal of amplifier 241.

The output terminal of amplifier 241 is electrically connected directly to output terminal 63, and is also electrically connected to output terminal 64 through inverter 217. Thus, in input circuit 206, output terminal 63 outputs the first oscillation signal S1, whereas output terminal 64 outputs the second oscillation signal S2. The signal S2 is generated by inverting the phase of the signal S1 by inverter 217. In the modified example 3, operational amplifier 241 is the active element, and capacitor 223 is the capacitive element.

Input circuit 2 may be modified into input circuit 208 as shown in the modified example 4 of FIG. 4. Input circuit 208 includes a plurality of transistors, capacitors 226 and 227, resistors 271-274, and output terminals 63 and 64. In the present exemplary embodiment, input circuit 208 includes transistors 251 and 252, capacitors 226 and 227, and resistors 271-274, but the numbers of transistors, capacitors, and resistors are not limited to the above-mentioned ones.

Transistor 251 is an npn bipolar transistor. The emitter of transistor 251 is electrically connected directly to input terminal 62. The collector of transistor 251 is electrically connected directly to output terminal 63, and is also electrically connected to input terminal 61 through resistor 271. The base of transistor 251 is electrically connected to input terminal 61 through resistor 273.

Transistor 252 is also an npn bipolar transistor. The emitter of transistor 252 is electrically connected directly to input terminal 62. The collector of transistor 252 is electrically connected directly to output terminal 64, and is also electrically connected to input terminal 61 through resistor 274. The base of transistor 252 is electrically connected to input terminal 61 through resistor 272.

Capacitor 226 is electrically connected between the collector of transistor 251 and the base of transistor 252. Capacitor 227 is electrically connected between the collector of transistor 252 and the base of transistor 251. In the modified example 4, transistors 251 and 252 are the active elements, and capacitors 226 and 227 are the capacitive elements.

In the modified example 4, capacitors 226 and 227 are connected to input terminal 61 not directly but through resistors 271 and 274. Capacitors 226 and 227 can have a more stable potential on the input terminal 61 side by being connected through active elements than through resistors.

Input circuits 2, 202, 204, 206, and 208 may be any circuit other than an oscillator circuit as long as they are configured to generate an output signal corresponding to the input signal. Similarly, control circuit 4 may be any circuit other than a charge-discharge circuit as long as it is configured to output to the output circuit a control signal corresponding to the output signal of the input circuit. Furthermore, isolation circuit 3 may be any circuit other than a boost circuit as long as it includes a plurality of capacitors and is configured to provide electrical isolation between the input circuit and control circuit 4.

As described above, driver circuit 1 of the present exemplary embodiment includes an input circuit (oscillator circuit), isolation circuit 3 (boost circuit), and control circuit 4 (charge-discharge circuit). The input circuit is electrically connected between input terminals 61 and 62, and generates output signals (the first oscillation signal S1 and the second oscillation signal S2) corresponding to input signals entered to input terminals 61 and 62. Control circuit 4 is electrically connected to output circuit 5, which is electrically connected between output terminals 71 and 72, and sends control signals corresponding to the output signals of the input circuit to output circuit 5. Isolation circuit 3 includes capacitors 31 and 32 electrically connected between the input circuit and control circuit 4 so as to provide electrical isolation between the input circuit and control circuit 4. The input circuit includes an active element (ex. inverter 211 in FIG. 2A) driven by an input signal; and a capacitive element electrically connected between the active element (ex. capacitor 221 in FIG. 2A) and one of input terminals 61 and 62.

The term “active element” means a circuit element having amplifying and switching functions when a voltage or current is applied, and more particularly, means a circuit element in which the potential of the output voltage becomes lower, as the potential of the input voltage becomes higher. The active element can be a transistor, an inverter, an operational amplifier, a comparator, etc.

In the above-described structure, isolation circuit 3 including capacitors 31 and 32 provides electrical isolation between input circuit 2 and control circuit 4. This feature reduces the consumption current, as compared with the conventional isolation circuit including a light-emitting element and a photovoltaic element. Meanwhile, the conventional semiconductor relay is hard to use under high temperature environment in which the light-emitting element has a low light output. In contrast, driver circuit 1 of the present exemplary embodiment can provide semiconductor relay 10 that can be used even under high temperature environment.

As in driver circuit 1 of the present exemplary embodiment, the input circuit (oscillator circuit) preferably includes at least one resistor (ex. resistor 231 in FIG. 2A) electrically connected between the input terminal and the output terminal of an active element (ex. inverter 211 in FIG. 2A).

Driver circuit 1 with the above-described structure can generate rectangular electrical signals.

As in driver circuit 1 of the present exemplary embodiment, at least one resistor is preferably the parasitic resistance of conductor 261 that is electrically connected between active elements (ex. inverters 213 and 215 in FIG. 2C).

The above structure does not need the provision of a resistor, thereby reducing driver circuit 1 in size and cost. The parasitic resistance of conductor 261 preferably has as low a resistance as possible so that input circuit 204 can be less subjected to ambient temperature.

As in driver circuit 1 of the present exemplary embodiment, the capacitive element is preferably the parasitic capacitance of the active element.

The above-described structure does not need the provision of a capacitive element, thereby reducing driver circuit 1 in size and cost.

As in input circuit 2, providing only one active element (ex. inverter 211 in FIG. 2A) reduces driver circuit 1 in size and cost. Meanwhile, as shown in input circuit 202, providing a plurality of active elements achieves stable oscillation.

As in driver circuit 1 of the present exemplary embodiment, control circuit 4 is preferably a charge-discharge circuit that charges and discharges the gate capacitances of switches 51 and 52 included in output circuit 5.

With the above-described structure, the gate capacitances of switches 51 and 52 can be charged and discharged.

As in driver circuit 1 of the present exemplary embodiment, the charge-discharge circuit preferably has semiconductor device 41 and bypass circuit 43. In that case, semiconductor device 41 is composed of a depletion-mode MOSFET that is electrically connected to the gates of switches 51 and 52. Bypass circuit 43 is composed of at least one diode, and is electrically connected between the gate and the source of device 41.

With the above-described structure, providing bypass circuit 43 achieves fast switching driver circuit 1 that is reduced in size and cost.

Semiconductor relay 10 of the present exemplary embodiment includes driver circuit 1 and semiconductor switches 51 and 52. Switches 51 and 52 compose output circuit 5 and are controlled by control signals.

Semiconductor relay 10 including driver circuit 1 described above has a low consumption current.

In the driver circuit and the semiconductor relay according to the present disclosure, the isolation circuit with capacitors provides electrical isolation between the input circuit and the control circuit. The isolation circuit has a lower consumption current than the conventional isolation circuit including the light-emitting element and the photovoltaic element.

What is claimed is:

1. A driver circuit electrically connected to a pair of input terminals and an output circuit, the driver circuit comprising:
an input circuit configured to generate output signals corresponding to input signals entered to the input terminals;
a control circuit configured to send control signals corresponding to the output signals to the output circuit; and
an isolation circuit including a plurality of capacitors electrically connected between the input circuit and the control circuit so as to provide electrical isolation between the input circuit and the control circuit,
wherein the input circuit includes:
an active element configured to be driven by the input signals; and
a capacitive element electrically connected between the active element and one of the input terminals.

2. The driver circuit of claim 1, wherein the input circuit further includes at least one resistor electrically connected between an input part and an output part of the active element.

3. The driver circuit of claim 2, wherein the resistor is a parasitic resistance of a conductor electrically connected to the active element.

4. The driver circuit of claim 1, wherein the capacitive element is a parasitic capacitance of the active element.

5. The driver circuit of claim 1, wherein the control circuit is a charge-discharge circuit configured to charge and discharge a gate capacitance of a semiconductor switch of the output circuit.

6. The driver circuit of claim 5, wherein the control circuit includes:
a semiconductor device composed of a depletion-mode metal-oxide-semiconductor field-effect transistor (MOSFET) and electrically connected to a gate of the semiconductor switch; and
a bypass circuit composed of at least one diode and electrically connected between a gate and a source of the semiconductor device.

7. The driver circuit of claim 1, wherein the isolation circuit is a charge-pump boost circuit including a diode.

8. A semiconductor relay comprising:
the driver circuit of claim 1; and
an output circuit including a semiconductor switch controlled by the control signals of the driver circuit.

9. The semiconductor relay of claim 8, wherein the input circuit further includes at least one resistor electrically connected between an input part and an output part of the active element.

10. The semiconductor relay of claim 9, wherein the resistor is a parasitic resistance of a conductor electrically connected to the active element.

11. The semiconductor relay of claim 8, wherein the capacitive element is a parasitic capacitance of the active element.

12. The semiconductor relay of claim 8, wherein the control circuit is a charge-discharge circuit configured to charge and discharge a gate capacitance of the semiconductor switch of the output circuit.

13. The semiconductor relay of claim 12, wherein the control circuit includes:
a semiconductor device composed of a depletion-mode metal-oxide-semiconductor field-effect transistor (MOSFET) and electrically connected to a gate of the semiconductor switch; and
a bypass circuit composed of at least one diode and electrically connected between a gate and a source of the semiconductor device.

14. The semiconductor relay of claim 8, wherein the isolation circuit is a charge-pump boost circuit including a diode.
